(19) United States
(12) Patent Application Publication
(10) Pub. No.: US 2004/0124421 A1
(43) Pub. Date: Jul. 1, 2004

(54) Light-emitting device and manufacturing method thereof

(75) Inventors: Shunpei Yamazaki, Tokyo (JP); Hisao Ikeda, Atsugi (JP); Makoto Udagawa, Tochigi (JP); Ryoji Nomura, Yamato (JP)

Correspondence Address: COOK, ALEX, MCFARRON, MANZO,, CUMMINGS & MEHLER, LTD., Suite 2850, 200 West Adams St., Chicago, IL, 60606, US

(73) Assignee: Semiconductor Energy Laboratory Co., Ltd.

(21) Appl. No.: 10/664,458

(22) Filed: Sep. 18, 2003

(30) Foreign Application Priority Data
Sep. 20, 2002 (JP) 2002-276389

(51) Int. Cl. H01L 27/15; H01L 31/12; H01L 33/00

(52) U.S. Cl. 257/79

(57) ABSTRACT

A light-emitting device that uses a light-emitting element which can be minimized its deterioration as a display element is provided. And also a light-emitting device which can control power consumption and enhance reliability by using the light-emitting element as a display element, and a manufacturing method thereof are provided. A light-emitting device in which the concentration of dopant is set in the range of no fewer than 0.001%, nor more than 0.35% by weight, a photosensitive organic resin film having an anode and an opening is disposed on a first passivation film, an anode, a cathode, and a light-emitting layer are overlapped in the opening, and the organic resin film and the cathode are covered with a second passivation film.

### BACKGROUND OF THE INVENTION

1. Field of the Invention

The present invention relates to a light-emitting device having a light-emitting element including an electroluminescent material to which a doping material is added as a display element, and a manufacturing method thereof.

2. Background of the Invention

Since a light-emitting element emits light by itself, the light-emitting element has high visibility and does not require a backlight required for a liquid crystal display device (LCD). Therefore, a light-emitting element is suitable for thin devices. Furthermore, the viewing angle of a light-emitting device is no limitation. Because of these advantages, a light-emitting device having a light-emitting element has recently attracted attentions as an alternative display device to a CRT and/or an LCD.

However, when a light-emitting device is put to practical, there is a problem that a light-emitting device has a short lifetime due to deterioration of electroluminescent layers.

Generally, an electroluminescent material is deteriorated due to water, oxygen, light, and heat, which speed up deterioration of the electroluminescent material. More particularly, the deterioration rate is dependent on the structure of a device for driving a light-emitting device, the characteristics of the electroluminescent material, a material of electrodes, a condition in the manufacturing processes, the method of driving the light-emitting device, and etc.

Even though voltage applied to an organic light-emitting element is constant, deterioration in a light-emitting element proceeds, the luminance is lowered since the amount of current which flows in the deteriorated light-emitting element is small. In this case, the luminance of a light-emitting element can be raised by increasing supply current and applied voltage. Nevertheless, it is a temporary consequence and then, increasing the amount of current causes deterioration of the light-emitting device quickly. This leads a vicious circle of much shorter lifetime of a light-emitting element. Also, it is not preferable because power consumption is also increased when the amounts of voltage and current are increased.

Reference 1: Japanese Patent Laid Open No. 2002-108285 describes that the decline of luminance can be prevented, regardless of deterioration of electroluminescence layers, by operating a transistor controlling current supplied to a light-emitting element in a saturation region, and keeping drain current constant.

As the reference 1 describes, drain current can be relatively kept uniformly by operating a drive transistor in a saturation region, even Vds is decreased instead of Vel being increased with the deterioration of a light-emitting element. Therefore, the decline of luminance can be prevented regardless of deterioration of a light-emitting element. But there is a problem that a transistor which operates in a saturation region has a high heat value according to the increased power consumption, compared with the transistor which operates in a linear region.

### SUMMARY OF THE INVENTION

The present invention has been made in view of the above, and an object of the present invention is therefore to provide a light-emitting element which can be minimized its deterioration. Also another object of the present invention is to provide a light-emitting device which can control power consumption and enhance reliability by using the light-emitting element as a display element, and a manufacturing method thereof.

The present inventors thought that when an amount of fluorescent pigment that is added to an electron transporting electroluminescent material that is called a host is reduced from 1.0% by weight that is a normal amount, an element having such a high emission efficiency as to enable to obtain high brightness at a smaller amount of current might be obtained.

Dopant such as quinacridone is likely to form a π-π stacking; accordingly, when a concentration thereof is made higher it easily associates. Molecules associated through the π-π stacking exhibit an emission (excimer emission) in a wavelength region longer than that of a normal fluorescence (monomer emission), and intensity thereof is also low. Accordingly, when an amount of dopant is increased, a ratio of the excimer emission to the monomer emission becomes relatively larger, resulting in a decrease in the emission intensity (concentration quenching). On the contrary, when an amount of the dopant is reduced, since an average distance between the dopant becomes larger, the molecules can be suppressed from associating, more specifically from forming second quantization. Accordingly, it is considered that as the amount of the dopant is made lower, the excimer emission is suppressed from occurring, resulting in predominant occurrence of the monomer emission.

In FIG. 1, emission spectra of light-emitting elements when a concentration of quinacridone derivative (DMQd) that is doped in Alq₃ is set at 1.0, 0.6, 0.5, 0.4 and 0.3% by weight are shown. The light-emitting element has a configuration such as shown in FIG. 2. Specifically, on anode 100 that is made of ITO that is a transparent conductive film, a layer of copper phthalocyanine (CuPc) having a film thickness of 20 nm as hole injection layer 101, a layer of 4,4′-bis [N-(1-naphtyl)-N-phenyl-amino]-biphenyl (hereinafter referred to as α-NPD) having a film thickness of 40 nm as hole transporting layer 102, a layer of DMQd-added Alq₃ having a film thickness of 37.5 nm as light-emitting layer 103, a layer of Alq₃ having a film thickness of 37.5 nm as electron transporting layer 104, a layer of CaF₂ having a film thickness of 1 nm as electron injection layer 105, and cathode 106 made of Al are sequentially laminated.

In Chem. 1, one of constitutional formulas (constitutional formula 1) of quinacridone derivatives is shown. FIG. 1 shows spectra when R in the chem. 1 is CH₃.

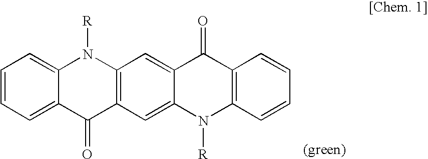

In the spectra shown in FIG. 1, in the vicinity of 545 nm and 575 nm, peaks corresponding to the monomer emission and the excimer emission, respectively, are observed. All the spectra are normalized with respect to a peak intensity in the vicinity of 545 nm that is assigned to 1.

In the spectra shown in FIG. 1, as the concentration of DMQd is diminished, the peak in the vicinity of 575 nm corresponding to the excimer emission decreases relatively in the intensity. From this, it is found that when the concentration of DMQd is lowered, the monomer emission occurs predominantly over the excimer emission.

Accordingly, in the present invention, with respect to an electron transporting electroluminescent material that is called a host, an amount of a fluorescent pigment that is doped is set at 0.001% by weight or more and 0.4% by weight or less, preferably 0.1% by weight or more and preferably 0.35% by weight or less. According to the above configuration, the monomer emission can be generated predominantly over the excimer emission. Accordingly, an element having such high emission efficiency as to allow obtaining high brightness at a low current amount can be obtained.

Furthermore, in the invention, an organic resin film that is used as a wall for separating the light-emitting elements between pixels and the light-emitting elements are sandwiched with an insulating film (hereinafter referred to as passivation film) that transmits moisture and oxygen with difficulty. Specifically, on a passivation film, an organic resin film for the separating wall and a light-emitting element are formed, and further thereon a passivation film is formed. The organic resin film for the separating wall, before or after an electroluminescent layer is formed and before the second passivation film is formed, is heated under a vacuum atmosphere to remove absorbed moisture and oxygen.

In general, the fluorescent pigments used as the dopant, similarly to the electroluminescent materials, are likely to be deteriorated due to moisture, oxygen, light, heat and so on. Accordingly, when a dope amount is lowered from an ordinary concentration to an order of such as from 10⁻¹ to 10⁻²% by weight that is lower than an ordinary concentration, since an absolute amount of the dopant becomes slight, the characteristics of the light-emitting element come to be easily influenced by the deterioration of the dopant, resulting in difficulty in securing the reliability of the light-emitting element. However, according to the invention, the use of the above configuration allows suppressing the dopant from deteriorating; accordingly, even when the concentration of the dopant is lowered to an order of from 0.001 to 0.1% by weight, the characteristics of the light-emitting element come to be influenced with difficulty by the deterioration of the dopant, resulting in an improvement in the reliability of the light-emitting element.

Furthermore, a fluorescent pigment is doped in order not only to improve the emission efficiency but in some cases also to convert an emission wavelength. For instance, tris-8-quinolilate aluminum complex (Alq₃) can separately cover a region on a longer wavelength side than green, and an emission color thereof is yellowish green. However, when a quinacridone derivative that is the dopant is added, it emits in green. When the excimer emission is generated predominantly over the monomer emission, it is difficult to obtain a green emission that is high in the purity. However, in the invention, the dopant can be inhibited from forming second quantization; accordingly, the monomer emission tends to occur predominantly over the excimer emission, resulting in enhancing the color purity.

According to the invention, since the emission efficiency of the light-emitting element can be increased, even when a transistor for controlling a current that is supplied to the light-emitting element (driving transistor) is operated in a saturation region, a sum of consumption powers of the driving transistor and the light-emitting element can be suppressed lower. In addition, when the driving transistor is operated in the saturation region, an effect of suppressing the brightness from decreasing owing to the deterioration of the light-emitting element can be additionally obtained.

In the invention, the electroluminescent material that is used as the host of the elecreoluminescent layer is not restricted to Alq₃. Furthermore, the fluorescent pigment that is used as the dopant is not restricted to quinacridone derivative.

According to the above configuration, the monomer emission can be generated predominantly over the excimer emission. Therefore, an element having such high emission efficiency as to allow obtaining high brightness at a low current amount can be obtained.

Furthermore, in the invention, an organic resin film that is used as a bank for separating light-emitting elements between pixels and the light-emitting elements are sandwiched between insulating films (hereinafter referred to as a passivation film) that transmits moisture and oxygen with difficulty. Therefore, even when the concentration of the dopant is on the order of 0.001 to 0.1% by weight, the characteristics of the light-emitting element come to be influenced with difficulty by the deterioration of the dopant with the result that the reliability of the light-emitting element can be improved.

However, in the invention, the dopant can be inhibited from forming second quantization; accordingly, the monomer emission tends to occur predominantly over the excimer emission, resulting in enhancing the color purity.

### BRIEF DESCRIPTION OF THE DRAWINGS

FIG. 1 shows emission spectra of Alq₃ added quinacridone derivative;

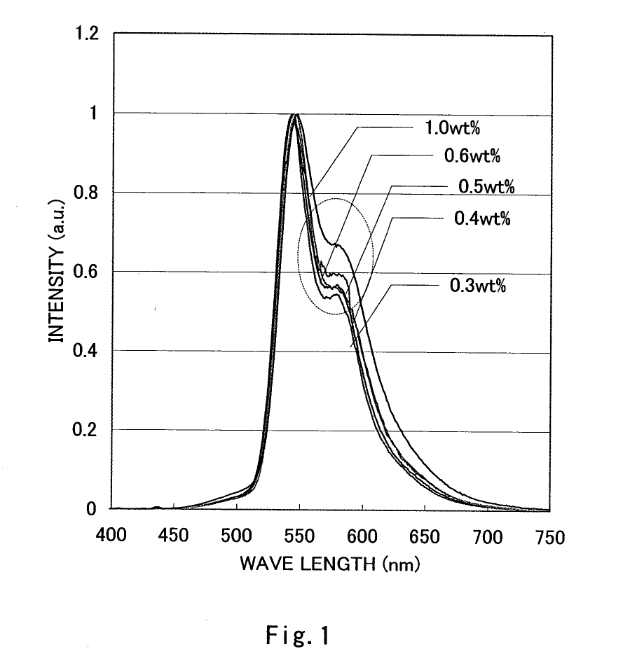

FIG. 2 is a diagram showing a sectional structure of a light-emitting element;

FIG. 3 is a diagram showing a cross sectional structure of a pixel of a light-emitting device;

FIG. 4 is a graph showing variations of the brightness with time;

FIGS. 5A and 5B are graphs showing a relationship of power consumption (mW) versus brightness (nt) and a relationship of panel temperature (degree centigrade) versus power consumption (mW);

FIGS. 6A and 6B are graphs showing a proportion of power consumption of a light-emitting element and a driving transistor;

FIG. 7 is a diagram showing a sectional structure of a light-emitting element;

FIGS. 8A and 8B are circuit diagrams of a pixel portion of a light-emitting device;

FIGS. 9A and 9B are circuit diagrams of a pixel portion of a light-emitting device;

FIGS. 10A to 10H are diagrams showing electronic apparatuses using a light-emitting device of the present invention;

FIG. 11 shows an appearance of a light-emitting device according to the present invention;

FIG. 12 is a graph showing a relationship of emission efficiency (cd/A) and concentration (% by weight) of quinacridone derivative (DMQd).

### DESCRIPTIOIN OF THE PREFERRED EMBODIMENTS

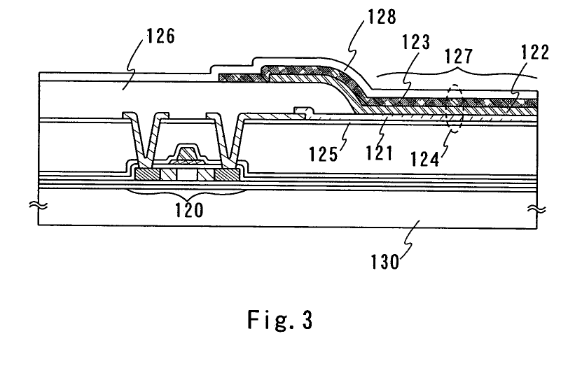

With reference to FIG. 3, a configuration of a pixel of a light-emitting device according to the invention will be explained. The light-emitting device includes a panel in which a light-emitting element is sealed and a module in a state where an IC and so on including the controller are mounted on the panel. In FIG. 3, reference numerals 121, 122 and 123, respectively, denote an anode, an electroluminescent layer and a cathode, and a portion where the anode 121 and the electroluminescent layer 122 are overlapped with the cathode 123 corresponds to light-emitting element 124. Furthermore, reference numeral 120 denotes a transistor (driving transistor) that controls a current that is supplied to the light-emitting element 124 and is connected directly or through other circuit elements in series to the light-emitting element 124.

The electroluminescent layer 122 has a configuration made of a single light-emitting layer or a configuration in which a plurality of layers including the light-emitting layer are laminated. In the invention, in the light-emitting layer, dopant is added by a concentration of 0.001% by weight or more and 0.4% by weight or less, preferably by 0.1% by weight or more and preferably by 0.35% by weight or less. According to the above configuration, the monomer emission is allowed to emit predominantly over the excimer emission; accordingly, an element having such a high emission efficiency as to allow obtaining high brightness at a small amount of current can be obtained.

The anode 121 is formed on the first passivation film 125. Furthermore, on the first passivation film 125, organic resin film 126 that is used as the separating wall is formed. The organic resin film 126 has opening 127; in the opening the anode 121, the electroluminescent layer 122 and the cathode 123 overlap each other, and thereby the light-emitting element 124 is formed.

Then, on the organic resin film 126 and the cathode 123, a second passivation film 128 is deposited. For both the first and second passivation films 125 and 128, a film that allows with difficulty in comparison with other insulating films transmitting substances that may cause the deterioration of the light-emitting element such as moisture and oxygen is used. Typically, a film comprising DLC, boron nitride film, alumina, or carbon nitride, or a film comprising silicon nitride formed by means of an RF sputtering can be preferably used. In that case, a film thickness thereof is desirably in the range of substantially from 10 to 200 nm. In particular, when DLC, boron nitride, or alumina high in the thermal conductivity is used in the first passivation film 125 or the second passivation film 128, heat generated by the light-emitting element 124 or the driving transistor 120 can be effectively dissipated; accordingly, the light-emitting element 124 can be suppressed from deteriorating. When the driving transistor 120 is operated in the saturation region in particular, in comparison with the case of being operated in a linear region, an amount of heat generation from the driving transistor 120 tends to be high; accordingly, the use of DLC, boron nitride, or alumina high in the thermal conductivity is effective from a viewpoint of suppressing the deterioration of the light-emitting element 124.

Furthermore, the organic resin film 126, before the electroluminescent layer 122 is formed, in order to remove absorbed moisture and oxygen, is heated under a vacuum atmosphere. Specifically, heat treatment is applied under the conditions of from 100 to 200 degree centigrade, for substantially from 0.5 to 1 hr and under a vacuum atmosphere. The vacuum is desirably set at 3×10⁻⁷ Torr or less, and, if possible, most desirably 3×10⁻⁸ Torr or less. In the case of an electroluminescent layer being deposited after the organic resin film 126 is heated under the vacuum atmosphere, when the electroluminescent film is maintained in the vacuum atmosphere until immediately before the deposition, the reliability can be further heightened.

Thus, when the organic resin film that is in direct contact with the electroluminescent layer and the light-emitting element are sandwiched with the passivation films difficult to transmit the moisture and oxygen and, before the electroluminescent layer is deposited, the organic resin film is heated, the dopant can be inhibited from deteriorating; accordingly, even when the concentration of the dopant is set in the range of from 0.001 to 0.1% by weight, the deterioration of the reliability due to the deterioration of the dopant can be suppressed low.

Furthermore, an end portion in the opening 127 of the organic resin film 126, in order that the electroluminescent layer 122 formed partially overlapping on the organic resin film 126 may not be broken at the end portion, is desirably formed roundish. Specifically, a radius of curvature of a curve that a section of the organic resin film in the opening depicts is desirably in the range of substantially from 0.2 to 2 [m.

According to the above configuration, the coverage of the electroluminescent layer and the cathode formed later can be made excellent, and the anode 121 and the cathode 123 can be inhibited from short-circuiting in the opening formed in the electroluminescent layer 122. Furthermore, by alleviating the stress on the electroluminescent layer 122, a defect called shrink in which a light-emitting region is diminished can be reduced, resulting in an improvement in the reliability.

In FIG. 3, as the organic resin film 126, an example is shown where a positive photosensitive acrylic resin is used. In the photosensitive organic resins, there are a positive type in which a portion exposed with an energy beam such as light, electrons, and ions is removed, and a negative type where an exposed portion remains. In the invention, the negative type organic resin film may be used.

The anode 121 can be formed with a transparent conductive film. Other than the ITO film, a transparent film in which from 2 to 20% of zinc oxide (ZnO) is mixed with indium oxide may be used. Furthermore, for the cathode 123, as far as being a conductive film low in the work function, other known materials can be used. For instance, Ca, Al, CaF, MgAg, AlLi and so on are desirable.

In FIG. 3, a configuration in which light emitted from the light-emitting element is irradiated toward substrate 130 is shown; however, a light-emitting element may be structured so that light directs toward a side opposite to the substrate 130.

Furthermore, in FIG. 3, the driving transistor 120 and the anode 121 of the light-emitting element are connected; however, according to the present invention, without restricting to this configuration, the driving transistor 120 and the anode 121 of the light-emitting element may be directly connected. However, in this case, the cathode is formed on the passivation film closer to the driving transistor 120 than the anode.

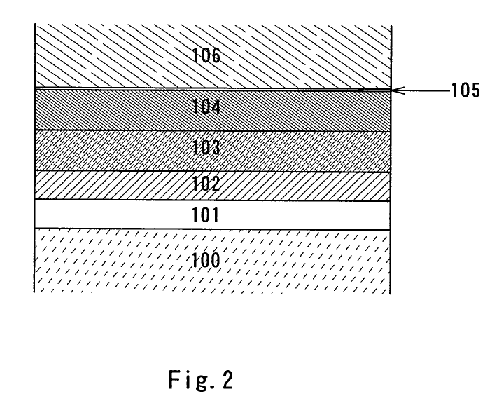

An active matrix light-emitting device that has a pixel having a sectional structure shown in FIG. 3 and is provided with a light-emitting element having a lamination structure the same as that of FIG. 2 was subjected to reliability test. In a light-emitting device used in the measurement, an area from which light emission is actually obtained occupies an area having a ratio of 40% in one pixel. The light-emitting device is driven so that a ratio of an emitting period in one frame period (duty ratio) may be 70% and measurement is performed with an initial brightness obtained by a measuring instrument set at 100 cd/mm². When calculating based on the ratio 40% of an area from which light emission is actually obtained and a value of the duty ratio of 70%, when the light-emitting element is continuously turned on, the brightness (intrinsic brightness) that is genuinely obtained from the light-emitting element is 320 cd/mm².

In the measurement, three kinds of light-emitting elements are used, the concentration of quinacridone derivative being 0.3% by weight in (I) and (II) and 1% by weight in (III). (II) and (III) are different in a film thickness of the α-NPD that is hole transporting layer 102 from the light-emitting element shown in FIG. 2, the film thickness being 60 nm for both.

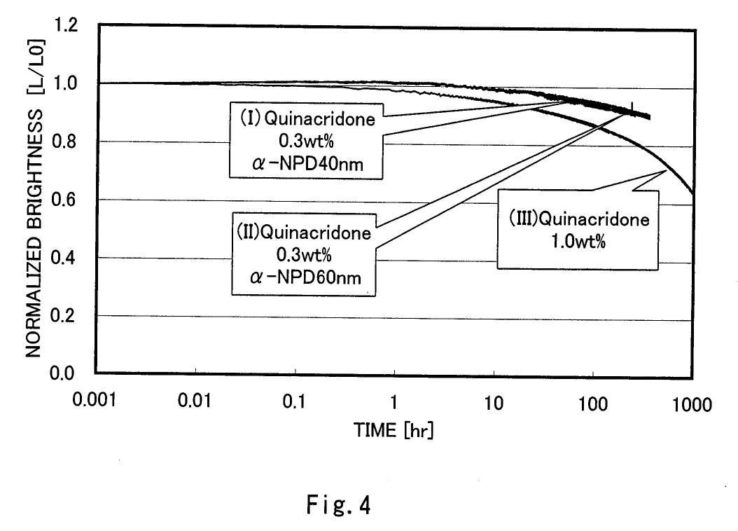

FIG. 4 is a graph showing measurements of the brightness with respect to the emission time period. The brightness in a vertical axis is normalized to an initial brightness assigned to 1. As shown in FIG. 4, it is found that the light-emitting devices corresponding to (I) and (II) are small in the decrease in the brightness relative to that of the light-emitting device corresponding to (III), that is, high in the reliability. In the light-emitting devices of (I) and (II), the decrease in the brightness was substantially 10% or less at 100 hr, and 20% or less at 1000 hr.

With an active matrix light-emitting device that has a pixel having a sectional structure shown in FIG. 3 and is provided with a light-emitting element having a lamination structure the same as that of FIG. 2, relationship of power consumption versus brightness and panel temperature versus power consumption were measured. In a light-emitting device used in the measurement, an area from which light emission is actually obtained occupies an area having a ratio of 40% in one pixel. The brightness was measured in a state where the light-emitting device was driven so that a ratio of a light-emitting period in one frame period (duty ratio) might be 70%.

Furthermore, the light-emitting devices that were used in the measurement used light-emitting elements having the concentrations of the quinacridone derivative of 0.3% by weight and 1% by weight. The two light-emitting devices are different from the light-emitting element shown in FIG. 2 in a film thickness of α-NPD that is the hole transporting layer 102, one of 0.3% by weight having a film thickness of 20 nm, the other one of 1.0% by weight having a film thickness of 60 nm.

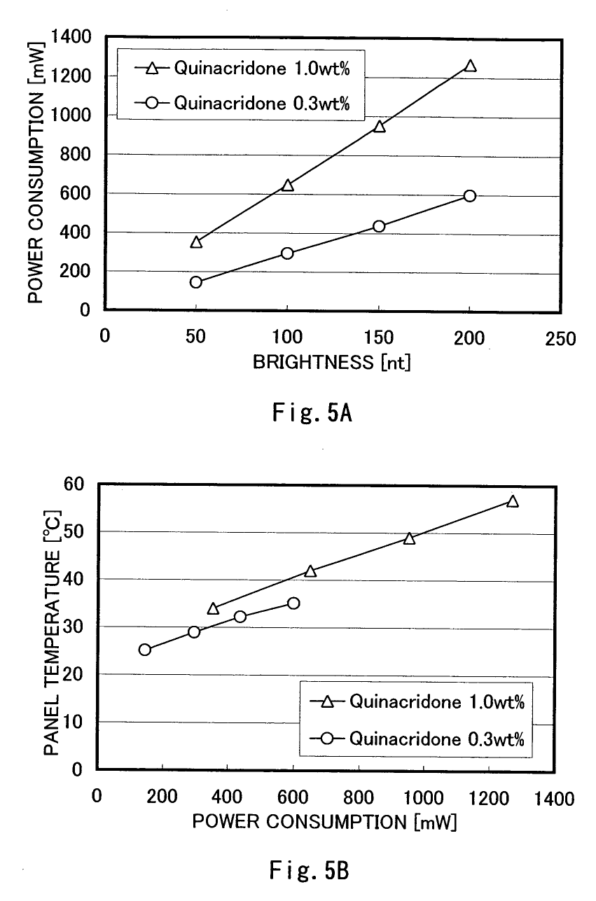

In FIG. 5A, relationship of power consumption (mW) versus brightness (nt) is shown. The power consumption shown in FIG. 5A is a total of the power consumption of the light-emitting element and that of the driving transistor operated in a saturation region. As shown in FIG. 5A, it is found that one of 0.3% by weight is lower in the power consumption and higher in the brightness than one of 1.0% by weight.

Furthermore, in FIG. 5B, relationship of panel temperature (degree centigrade) versus power consumption (mW) is shown. The power consumption shown in FIG. 5B is a total of the power consumption of the light-emitting element and that of the driving transistor operated in a saturation region. The panel temperature was measured at a portion that overlaps with a pixel portion of a substrate on which the pixel portion is formed. From FIG. 5B, it is found that even under the same power consumption, one of 1.0% by weight exhibits a higher temperature rise of the panel than one of 0.3% by weight. The temperature rise promotes the deterioration of the light-emitting element, resulting in causing the deterioration of the reliability. Accordingly, in view of the deterioration due to the temperature rise, one of 0.3% by weight is higher in the reliability than one of 1.0% by weight.

From FIGS. 5A and 5B, relationship between the brightness and the panel temperature can be indirectly found. For instance, in the case of one of 0.3% by weight, the brightness of 200 nt corresponds to the power consumption of 600 mW, and in this case, the panel temperature is 40 degree centigrade or less. Furthermore, the brightness of 130 nt corresponds to the power consumption of 400 mW, and in this case, the panel temperature is 35 degree centigrade or less.

The power consumption shown in FIGS. 5A and 5B is a total of the power consumption of the light-emitting element and that of the driving transistor. Among the total power consumption that contributes to the temperature rise, ratios of the respective power consumptions of the light-emitting element and the driving transistor are different depending on whether the driving transistor is operated in the saturation region or in the linear region.

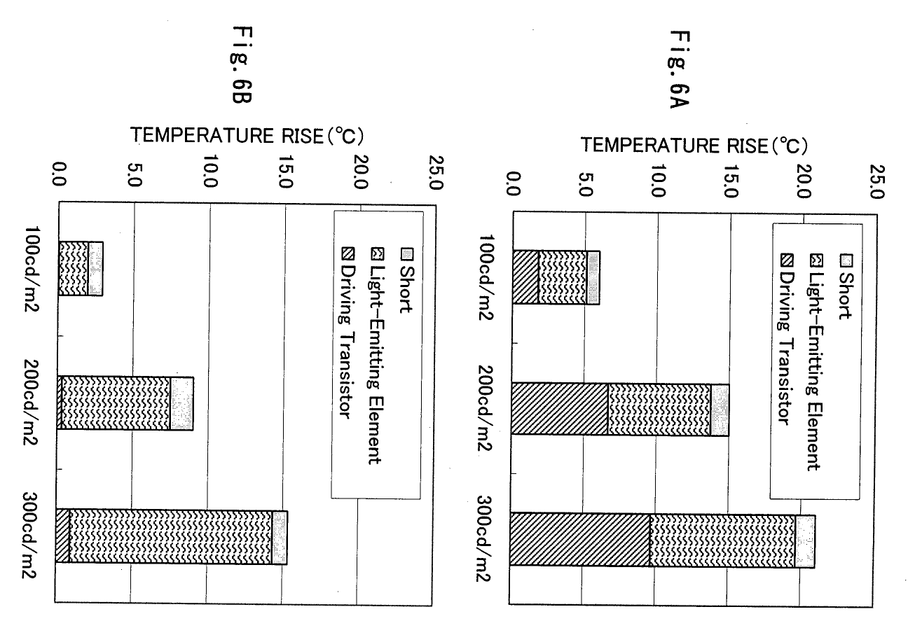

FIG. 6A shows relationship of the panel temperature versus the brightness obtained by simulation when the driving transistor is operated in the saturation region. FIG. 6B shows relationship of the panel temperature versus the brightness obtained by simulation when the driving transistor is operated in the linear region.

In the light-emitting device used in the measurement shown in FIGS. 6A and 6B, the concentration of quinacridone derivative is 1.0% by weight and the ratio of the area from which emission is actually obtained occupies 40% in the pixel. The brightness is measured assuming a state where the light-emitting device is driven so that the ratio of the emitting period in one frame period (duty ratio) may be 70%.

The panel temperature shows the temperature difference from a temperature when the device started to emit. The simulation was performed according to the following procedure. First, two panels are prepared and, between an anode and a cathode of the light-emitting element, the same voltage is applied. Furthermore, between a source and a drain of a driving transistor connected in series with the light-emitting element, different voltages are applied between the two panels. Then, the temperature difference generated between the two panels is measured. From the temperature difference between the two panels and the voltage difference between the source and the drain, in each of the operating regions, the ratios of the power consumptions that contributed to the temperature rises of the light-emitting element and the driving transistor were calculated.

From FIGS. 6A and 6B, it is found that the power consumptions contributed to the temperature rise do not show a large difference between the saturation region and the linear region. The ratio of the temperature rise due to the light-emitting element is substantially one half in the saturation region and substantially 90% in the linear region. In FIGS. 6A and 6B, the simulation was performed with the light-emitting device having the concentration of quinacridone of 1.0% by weight; however, it is considered that the substantially same tendency will result also in the case of 0.3% by weight.

Accordingly, it is found that since the power consumption of the light-emitting element is a sum of the power consumption contributing to light emission and the power consumption contributing to heat generation, when the light-emitting efficiency is heightened, the temperature of the panel can be effectively suppressed from rising.

Accordingly, from FIGS. 6A and 6B, it is found that in FIG. 5B, one of 0.3% by weight, being higher in the light-emitting efficiency than one of 1.0% by weight, even at the same power consumption, could be suppressed from rising in the panel temperature.

Furthermore, from comparison of FIGS. 6A and 6B, it is found that in the saturation region, the power consumption of the driving transistor that contributes to the temperature rise is higher than in the linear region, accordingly a sum of the power consumptions of the driving transistor and the light-emitting element is also higher. However, from FIGS. 5A and 5B, it is considered that when the dopant concentration is set at 0.3% by weight like in the invention, the light-emitting efficiency of the light-emitting element can be heightened; accordingly, even in the saturation region, the sum of the power consumptions of the driving transistor and the light-emitting element can be suppressed low. In addition, by operating the driving transistor in the saturation region, an effect of suppressing the lowering of the brightness resulting from the deterioration of the light-emitting element can be obtained.

The light-emitting element in the invention has a layer (electroluminescent layer) including an electroluminescent material in which when an electric field is applied between an anode and a cathode luminescence (electroluminescence) can be obtained. The electroluminescent layer is disposed between an anode and a cathode and made of a single layer or a plurality of layers. The luminescence in the electroluminescent layer includes luminescence that is generated when an excited singlet state returns to a ground state (fluorescence) and luminescence that is generated when an excited triplet state returns to a ground state (phosphorescence).

In the light-emitting element, a hole injection layer, an electron injection layer, a hole transporting layer or an electron transporting layer may be made solely of an inorganic compound or may be made of a material in which an inorganic compound is mixed in an organic compound. Furthermore, these layers may be partially mixed each other.

Furthermore, the transistor that is used in the light-emitting device according to the invention may be one formed by use of single crystal silicon or a thin film transistor formed by use of polycrystalline silicon or amorphous silicon. Still furthermore, it may be a transistor that uses an organic semiconductor.

Still furthermore, the organic resin film that is used as a separating wall, without restricting to the photosensitive acrylic resins, may be made of other organic resins such as polyimide, polyethylene, polytetrafluoroethylene, polystyrene, benzocyclobutene, poly(p-phenylenevinylene), polyvinyl chloride, and polyparaxylene base resins.

### EMBODIMENTS

### Embodiment 1

In the present embodiment, a method of manufacturing a light-emitting element having a lamination structure shown in FIG. 2 will be explained.

First, after a substrate having an anode made of ITO was heated in a vacuum atmosphere at 150 degree centigrade for 30 minutes, CuPc was deposited on the substrate by use of a vapor deposition process into a film having a thickness of 20 nm at a deposition rate of 0.1 nm/sec.

Subsequently, by use of the vapor deposition process, α-NPD having a film thickness of 40 nm was deposited at a deposition rate of 0.2 nm/sec. Then, Alq₃ and DMQd were deposited together by use of the vapor deposition process, and thereby DMQd-added Alq₃ having a film thickness of 37.5 nm was deposited. At this time, a concentration of DMQd is set at 0.001% by weight or more and 0.4% by weight or less, preferably at 0.1% by weight or more, and preferably at 0.35% by weight or less. Furthermore, the deposition rate of Alq₃ was set at 0.2 nm/sec.

Next, by use of the vapor deposition process, Alq₃ is deposited in a film having a thickness of 37.5 nm at the deposition rate of 0.2 nm/sec. Alq₃, by shielding DMQd that is a deposition source by use of a shutter or the like after the DMQd-added Alq₃ was deposited, can be continuously deposited.

Subsequently, by use of the vapor deposition process, CaF₂ is deposited into a film having a thickness of 1 nm at the deposition rate of 0.01 nm/sec. In the vapor deposition process, CaF₂ is heated by means of resistance heating and vaporized.

In the next place, Al is deposited by use of the vapor deposition process in a film having a thickness of 20 nm. In the vapor deposition process, Al is heated by means of resistance heating and vaporized.

When a set of these processes is continuously carried out without exposing to air, the reliability of the light-emitting element can be increased.

In FIG. 2, CuPc is used as the hole injection layer 101; however, in place of CuPc, polythiophene (PEDOT) may be used. In this case, on the ITO that is the anode, a solution of PEDOT in which ethanol is used as a solvent is coated by use of a spin coat process at 500 rpm so as to be a film thickness of 60 nm.

Subsequently, heat treatment is applied and thereby ethanol contained in the film of PEDOT is vaporized. The heat treatment is applied in such a manner that heating for instance at 80 degree centigrade for 10 minutes may be followed by heating at 200 degree centigrade for substantially 1 hr.

In the next place, under a vacuum atmosphere, heat treatment is applied at 150 degree centigrade for substantially 30 minutes. Processes thereafter are similar to those in the case where CuPc is used as the hole injection layer 101.

In the present invention, the lamination structure of the light-emitting element and the film thickness thereof are not restricted to one shown in FIG. 2.

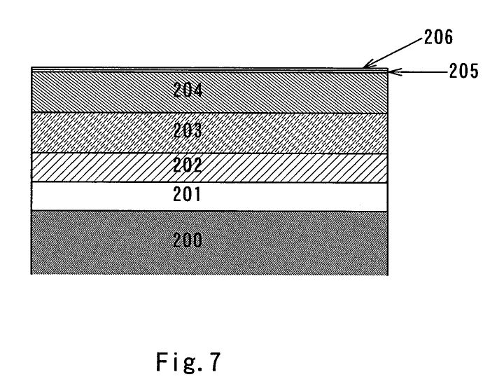

Furthermore, in FIG. 2, light is emitted from an anode side of the light-emitting element; however, the invention is not restricted thereto. In FIG. 7, a configuration of a light-emitting element in which light is emitted from a cathode side is shown.

In FIG. 7, on anode 200 made of TiN, CuPc having a film thickness of 20 nm as hole injection layer 201, α-NPD having a film thickness of 40 nm as a hole transporting layer 202, DMQd-added Alq₃ having a film thickness of 37.5 nm as a light-emitting layer 203, Alq₃ having a film thickness of 37.5 nm as an electron transporting layer 204, CaF₂ having a film thickness of 1 nm as an electron injection layer 205 and a cathode 206 made of Al having a film thickness in the range of from 10 to 30 nm are laminated in turn. In FIG. 7, as the anode 200 a material that does not transmit light is used, and the cathode 204 is formed in a film thickness of from 10 to 30 nm so that light may transmit therethrough and thereby light emitted from the light-emitting element may be obtained from the cathode 206 side. In order to obtain light from the cathode side, other than a method of thinning the film, ITO to which Li is added to lower the work function may be used.

When an electroluminescent layer is formed by use of the vapor deposition process, an inner wall of a chamber where the vapor deposition process is carried out is desirably subjected to electrolytic polishing, and furthermore, by use of a cryopump when evacuating, moisture can be efficiently removed.

### Embodiment 2

In the present embodiment, a configuration of a pixel of the light-emitting device used in FIGS. 4, 5 and 6 will be explained.

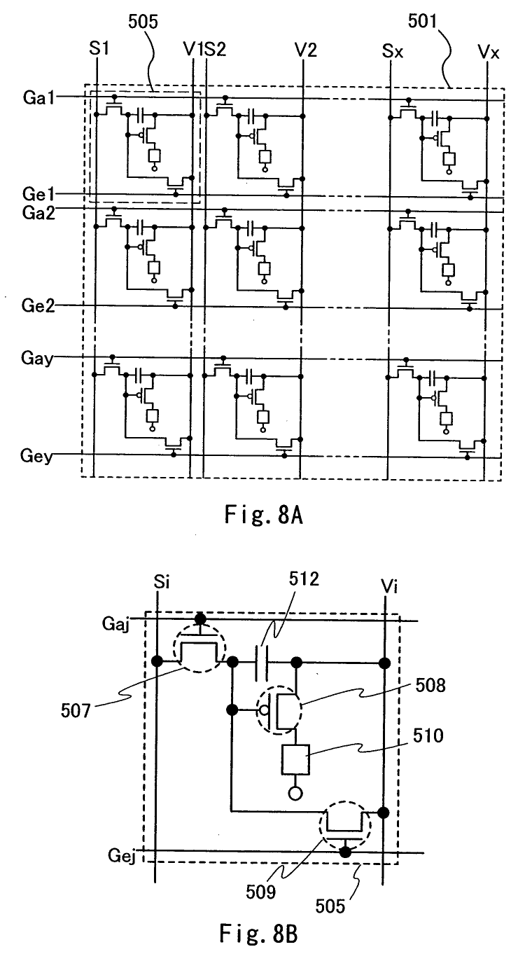

In FIG. 8A, a circuit diagram of a pixel portion of a light-emitting device according to the invention is shown. In FIG. 8A, pixel portion 501 is provided with signal lines (S1 through Sx), source lines (V1 through Vx), first scanning lines (Ga1 through Gay) and second scanning lines (Ge1 through Gey).

A region provided with one of the signal lines (S1 through Sx), one of the source lines (V1 through Vx), one of the first scanning lines (Ga1 through Gay) and one of the second scanning lines (Ge1 through Gey) corresponds to pixel 505. The pixel portion 501 is provided with a plurality of pixels 505 in matrix.

An enlarged view of the pixel 505 is shown in FIG. 8B. In FIG. 8B, reference numeral 507 denotes a switching transistor. A gate of the switching transistor 507 is connected to the first scanning line Gaj (j=1 through y). As to a source and a drain of the switching transistor 507, one of these is connected to the signal line Si (i=1 through x) and the other one is connected to a gate of driving transistor 508.

In the present invention, the connection, if not particularly referred to, means electrical connection.

A gate of erasing transistor 509 is connected to the second scanning line Gej (j=1 through y). As to a source and a drain of the erasing transistor 509, one of these is connected to the source line Vi (i=1 through x) and the other one is connected to a gate of the driving transistor 508.

As to a source and a drain of the driving transistor 508, one of these is connected to a source line Vi and the other one is connected to a pixel electrode that light-emitting element 510 has.

The light-emitting element 510 includes an anode, a cathode and an electroluminescent layer interposed between the anode and the cathode. When the anode is connected to the source or the drain of the driving transistor 508, the anode and the cathode, respectively, become a pixel electrode and an opposite electrode. On the contrary, when the cathode is connected to a source or a drain of the driving transistor 508, the cathode and the anode, respectively, become a pixel electrode and an opposite electrode.

When the anode is the pixel electrode, the driving transistor 508 is desirably a p-channel transistor. Furthermore, when the cathode is the pixel electrode, the driving transistor 508 is desirably an n-channel transistor.

To each of the opposite electrode and the source line Vi of the light-emitting element 510, a voltage is applied from a power supply. Voltage difference between the opposite electrode and the source line is maintained at a value that allows, when the driving transistor is turned on, applying a voltage of a forward direction bias to the light-emitting element.

Of two electrodes that retention capacitance 512 has, one is connected to the source line Vi and the other one is connected to the gate of the driving transistor 508. The retention capacitance 512 is disposed, when the switching transistor 505 is in a state of non-selection (off-state), to retain a gate voltage of the driving transistor 508. In FIG. 8B, a configuration in which the retention capacitance 512 is disposed is shown; however, the present invention, without restricting to the configuration, may be configured so that the retention capacitance 512 is not disposed.

When the switching transistor 507 is turned on according to the potential of the first scanning line Gaj, a potential of a video signal inputted into the signal line Si is supplied to a gate of the driving transistor 508. According to the potential of the inputted video signal, a gate voltage (voltage difference between the gate and the source) of the driving transistor 508 is determined. A drain current of the driving transistor 508 that is flowed by the gate voltage is supplied to the light-emitting element 510, and thereby the light-emitting element 510 emits owing to the supplied current.

Furthermore, when the erasing transistor 509 is turned on according to a potential of the second scanning line Gej, the potential of the source line Vi is supplied to both of the gate and the source of the driving transistor 508; accordingly, the driving transistor 508 is turned off, resulting in a forced termination of the emission of the light-emitting element 510.

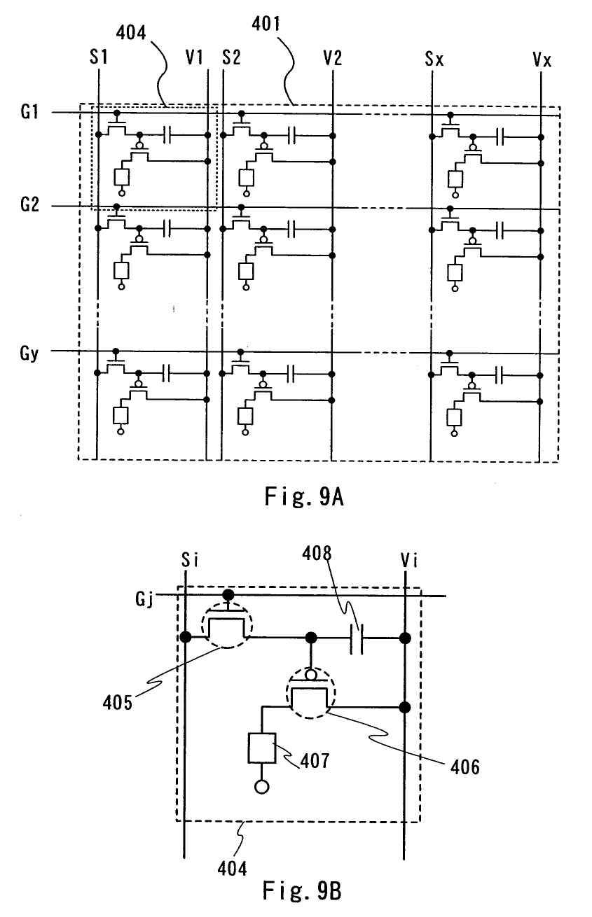

In the next place, in FIG. 9A, a circuit diagram of a pixel portion of a light-emitting device having a different configuration from that shown in FIGS. 8A and 8B is shown. Pixel portion 401 is provided with signal lines (S1 through Sx), source lines (V1 through Vx), and scanning lines (G1 through Gy).

In the case of the present embodiment, a region that is provided with any one of the signal lines (S1 through Sx), any one of the source lines (V1 through Vx) and any one of the scanning lines (G1 through Gy) corresponds to pixel 404. In the pixel portion 401, a plurality of pixels 404 is disposed in matrix.

An enlarged view of the pixel 404 is shown in FIG. 9B. In FIG. 9B, reference numeral 405 denotes a switching transistor. A gate of the switching transistor 405 is connected to a scanning line Gj (j=1 through y). Of a source and a drain of the switching transistor 405, one is connected to the signal line Si (i=1 through x) and the other one is connected to a gate of driving transistor 406.

Furthermore, of a source and a drain of driving transistor 406, one is connected to a source line Vi (i=1 through x) and the other one is connected to a pixel electrode of light-emitting element 407.

The light-emitting element 407 includes an anode, a cathode and an electroluminescent layer interposed between the anode and the cathode. When the anode is connected to the source or the drain of the driving transistor 406, the anode and the cathode, respectively, become a pixel electrode and an opposite electrode. On the contrary, when the cathode is connected to a source or a drain of the driving transistor 406, the cathode and the anode, respectively, become a pixel electrode and an opposite electrode.

When the source or the drain of the driving transistor 406 is connected to an anode of the light-emitting element 407, the driving transistor 406 is desirably a p-channel transistor. Furthermore, when the source or the drain of the driving transistor 406 is connected to a cathode of the light-emitting element 407, the driving transistor 406 is desirably an n-channel transistor.

To each of the opposite electrode and the source line Vi of the light-emitting element 407, a voltage is applied from a power supply. Voltage difference between the opposite electrode and the source line is maintained at a value that allows, when the driving transistor is turned on, applying a voltage of a forward direction bias to the light-emitting element.

Of two electrodes that retention capacitance 408 has, one is connected to the source line Vi and the other one is connected to the gate of the driving transistor 406. The retention capacitance 408 is disposed, when the switching transistor 405 is in a state of non-selection (off-state), so as to retain a gate voltage of the driving transistor 406. In FIG. 9B, a configuration in which the retention capacitance 408 is disposed is shown; however, the present invention, without restricting to the configuration, may be configured so that the retention capacitance 408 is not disposed.

When the switching transistor 405 is turned on according to the potential of the scanning line Gj, a potential of a video signal inputted into the signal line Si is supplied to a gate of the driving transistor 406. According to the potential of the inputted video signal, a gate voltage (voltage difference between the gate and the source) of the driving transistor 406 is determined. A drain current of the driving transistor 406 that is flowed by the gate voltage is supplied to the light-emitting element 407, and thereby the light-emitting element 407 emits owing to the supplied current.

In the light-emitting devices shown in FIG. 7 and FIGS. 8A and 8B, the video signals may be analogue one or digital one. In the case of the digital signal, when a period during which the light-emitting element emits (emission period) is controlled, gradation display can be realized.

The configurations shown in the embodiments are one example of the light-emitting device according to the invention, and the present invention is not restricted to the configuration. Furthermore, in FIG. 7 and FIGS. 8A and 8B, the video signal is inputted as a voltage; however, the present invention can be applied to a light-emitting device that inputs the video signal as a current.

When attention is paid to one pixel, an active light-emitting device tends to be longer in the light-emitting period in one frame period than a passive light-emitting device and this tendency becomes more remarkable as the number of pixels increases. The longer a continuously emitting period, the more accelerated in the deterioration of the light-emitting element. Accordingly, when the brightness of the light-emitting element is assumed to be the same in the respective pixels of the active one and those of the passive one, the active one is likely to be more deteriorated. Accordingly, the inventive configuration is more effective to the active matrix light-emitting device.

The present embodiment can be applied in combination with embodiment 1.

### Embodiment 3

In this embodiment, a forming method of an organic resin film used for a bank is descried. When an organic resin film is formed using a positive type photosensitive acrylic, the organic resin film is formed by spin coating and baking it. It is noted that the film thickness of the organic resin film is made to be approximately 0.7 to 5 um (more preferably, in the range from 2 to 4 um) after baking the film.

Next, the portion where the opening is contemplated to form is exposed to the light using a photomask. Then, after it has been developed with a developer whose major component is TMAH (Tetramethyl Ammonium Hydroxide), the substrate is dried and baked at 220° C. for about one hour. Then, the organic resin film with the opening is formed.

It should be noted that since a positive type photosensitive acrylic is colored in a light brown, when the luminescence from the light-emitting element goes toward the substrate side, the decolorizing treatment is provided. In this case, prior to the baking, the whole of the photosensitive acrylic after the development is again exposed to the light. The exposure to the light at this time is made to completely perform the exposure by irradiating a rather intense light and making the irradiating time longer comparing to the exposure for forming the opening. For example, when a positive type acrylic resin having a film thickness of 2 um is decolorized, in the case where a projection exposure system (concretely, MPA made by Canon, Co., Ltd.) utilizing the multiwavelength light including g line (436 nm), h line (405 nm) and i line (365 nm), which are spectral beams of super high pressure mercury vapor lamp is used, the radiation is performed for about 60 seconds. The positive type acrylic resin is completely decolorized by this exposure.

Moreover, in this embodiment, after the development, the substrate is baked at 220° C., however, it may be baked at a high temperature of 220° C. after baking at a low temperature of about 100° C. as a prebake following the development.

When an organic resin film is formed using a negative type photosensitive acrylic, an organic resin film other than the portion where the opening is contemplated to form is exposed to the light. Thereafter, eliminating the portion where the exposure to the light is not performed by the development, an organic resin film having an opening portion is formed.

Moreover, this embodiment can be freely combined with Embodiment 1 or Embodiment 2.

### Embodiment 4

In this embodiment, typical electroluminescent materials using for a light-emitting layer and typical fluorescence pigments using for dopant is described.

Electroluminescent materials used for light-emitting elements are roughly divided into low molecular weight materials and high molecular weight materials. A light-emitting device of the present invention can use either low molecular weight electroluminescent materials or high molecular weight electroluminescent materials.

Low molecular weight electroluminescent materials are formed into films by vapor deposition. Therefore low molecular weight electroluminescent materials can be easily formed into laminate structure and increased in the efficiency by stacking films of different functions such as a hole transporting layer and an electron transporting layer. Certainly, a hole transporting layer and an electron transporting layer are not distinctly present, as described as Japanese Patent Laid Open No. 2001-020817, for example, layers of mixed state are present singularly or plurally for obtaining the light-emitting device having long lifetime and high emission efficiency.

Typical examples of low molecular weight electroluminescent materials include Alq₃ shown in the following constitutional formula 2 of Chem. 2, BAlq₂ shown in the constitutional formula 3 of Chem. 3, Almq₃ shown in the constitutional formula 4 of Chem. 4, DPVBi shown in the constitutional formula 5 of Chem. 5, PVK shown in the constitutional formula 6 of Chem. 6 and a triphenyl amine derivative (TPD).

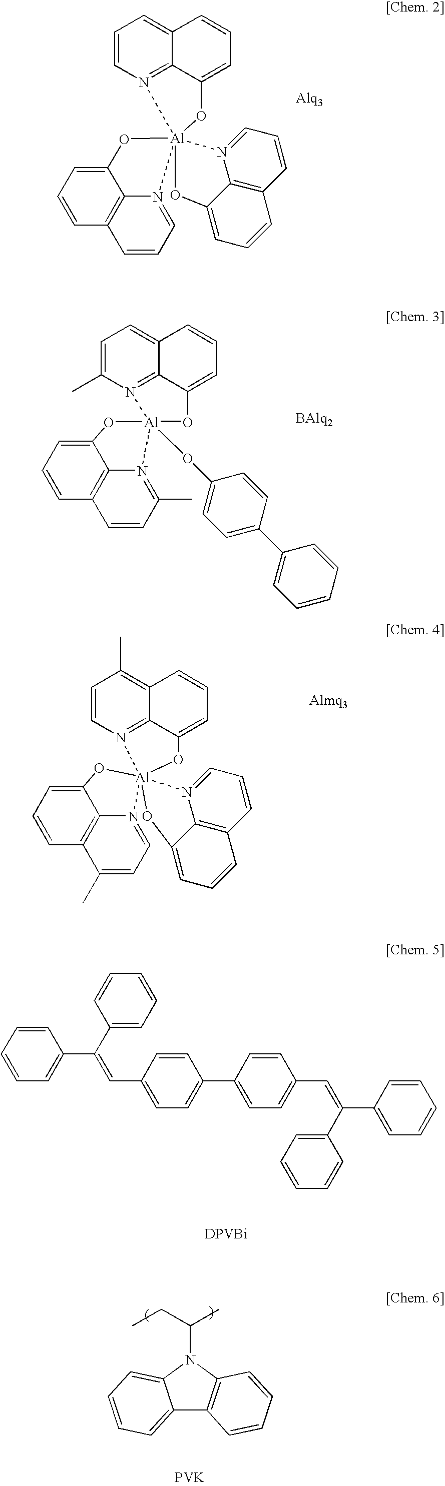

On the other hand, high molecular weight electroluminescent materials have higher physical strength than that of low molecular weight and elements formed of high molecular weight electroluminescent materials are highly durable. High molecular weight electroluminescent materials can be formed into films by application, and therefore manufacturing the elements from them is relatively easy.

The structure of a light-emitting element formed of a high molecular weight electroluminescent material is basically the same as the structure of a light-emitting element formed of a low molecular weight electroluminescent material, and is composed of a cathode, an organic light-emitting layer, and an anode. However, it is difficult to form from a high molecular weight electroluminescent material an organic light-emitting layer having a laminate structure as one formed of a low molecular weight electroluminescent material. The most popular of known laminate structures for an organic light-emitting layer formed of a high molecular weight electroluminescent material is the two-layer structure. Specifically, the two-layer structure is a light-emitting layer and hole transporting layer that are sandwiched between a cathode and an anode. Ca may be used as a cathode material in a light-emitting element formed of a high molecular weight electroluminescent material.

The color of emission from an element is determined by the material of its light-emitting layer. Accordingly, a light-emitting element that emits light of desired color can be obtained by selecting an appropriate light-emitting layer material. Typical examples of high molecular weight electroluminescent material that can be used to form a light-emitting layer include polyparaphenylenevinylene materials, polyparaphenylene materials, polythiophene materials, and polyfluorene materials.

Examples of the polyparaphenylenevinylenes include poly (paraphenylenevinylene) [PPV] derivatives such as poly (2,5-dialkoxy-1,4-phenylenevinylene) [RO-PPV], poly (2-(2′-ethyl-hexoxy)-5-methoxy-1,4-phenylenevinylene)[MEH-PPV], and poly (2-dialkoxyphenyl-1,4-phenylenevinylene) [ROPh-PPV].

Examples of the polyparaphenylenes include polyparaphenylene [PPP] derivatives such as poly(2,5-dialkoxy-1,4-phenylene) [RO-PPP], and poly (2,5-dihexoxy-1,4-phenylene).

Examples of the polythiophenes include polythiophene [PT] derivatives such as poly(3-alkylthiophene) [PAT], poly(3-hexylthiophene) [PHT], poly (3-cyclohexylthiophene) [PCHT], poly(3-cyclohexyl-4-methylthiophene) [PCHMT], poly(3,4-dicyclohexylthiophene) [PDCHT], poly[3-(4-octylphenyl)thiophene] [POPT], and poly [3-(4-octylphenyl)-2,2-bithiophene] [PTOPT].

Examples of the polyfluorenes include polyfluorene [PF] derivatives such as poly(9,9-dialkylfluorene) [PDAF], and poly(9,9-dioctylfluorene) [PDOF].

Injection of holes from the anode can be improved when a film of high molecular weight electroluminescent material capable of transporting holes is sandwiched between an anode and a light-emitting layer that is formed of a high molecular weight electroluminescent material. Generally, the hole transporting high molecular weight electroluminescent material together with an acceptor material is dissolved into water, and the obtained solution is applied by spin coating. Since the hole transporting high molecular weight electroluminescent material is insoluble in an organic solvent, a film of the hole transporting high molecular weight electroluminescent material can form a laminate with light-emitting electroluminescent materials described above.

Examples of the hole transporting high molecular weight electroluminescent material include a mixture of PEDOT and camphor sulfonic acid (CSA) that is an acceptor material, and a mixture of polyaniline (PANI) and polystyrene sulfonic acid (PSS) that is an acceptor material.

As well as the low molecular weight and the high molecular weight electroluminescent materials described above, so-called intermediate molecular weight electroluminescent materials, which have molecularity equal to or less than 20, and have a molecular chain length equal to or less than 10 um, and which do not have sublimability can be used.

Also, dopant is not limited to quinacridone derivative (DMQd) shown in the constitutional formula 1, and other known dopant such as Eu complex (constitutional formula 7 of Chem. 7), Nile red (constitutional formula 8 of Chem. 8), rhodamine B (constitutional formula 9 of Chem. 9), DCM (R═Me) (constitutional formula 10 of Chem. 10), phthalocyanine (constitutional formula 11 of Chem. 11), DCM2 (constitutional formula12 of Chem. 12), perylenetetracarboxylic diimide (constitutional formula 13 of Chem. 13), P1(constitutional formula 14), squaric acid derivative (constitutional formula 15 of Chem. 15), Tb complex (constitutional formula 16 of Chem. 16), rubrene (constitutional formula 17 of Chem.17), Dy complex(constitutional formula 18 of Chem. 18), fluorescein (constitutional formula 19 of Chem. 19), coumarin 6 (constitutional formula 20 of Chem. 20), perylene(constitutional formula 21 of Chem. 21), DPA (constitutional formula 22 of Chem. 22), coumarin derivative (constitutional formula 23 of Chem. 23), distyryl-amine(DSA) derivative (constitutional formula 24 of Chem. 24) distyryl-allylene derivative (constitutional formula 25 of Chem. 25), 2DSP (constitutional formula 26 of Chem. 26), BczVBi (constitutional formula 27 of Chem. 27), pyrrolopyrrole derivative (constitutional formula 28 of Chem. 28), pyrazoline (constitutional formula 29 of Chem. 29), naphthaquinacridone (constitutional formula 30 of Chem. 30), lophine (constitutional formula 31 of Chem. 30), diamino-stilbene derivative (constitutional formula 32 of Chem. 32), or decacyclene (constitutional formula 33 of Chem. 33) can be used.

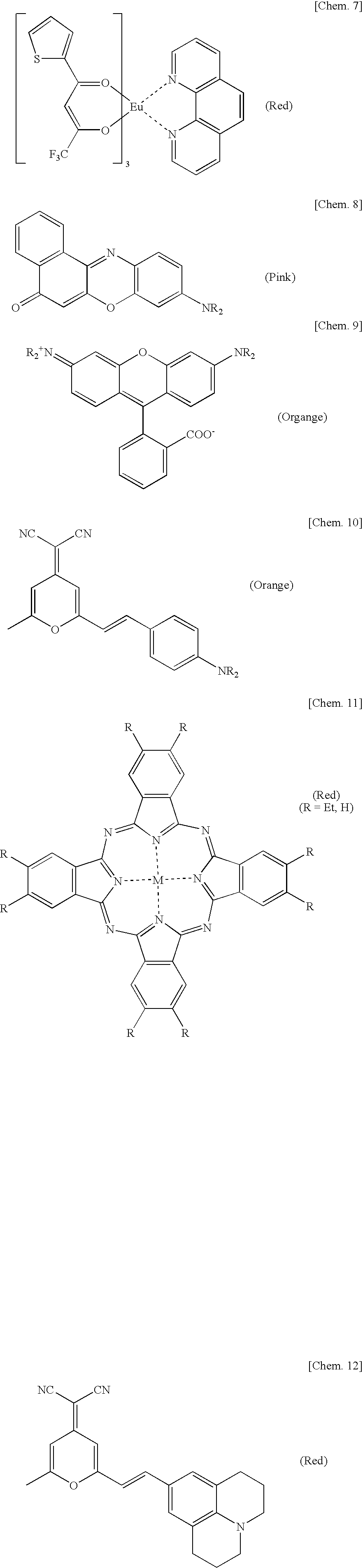

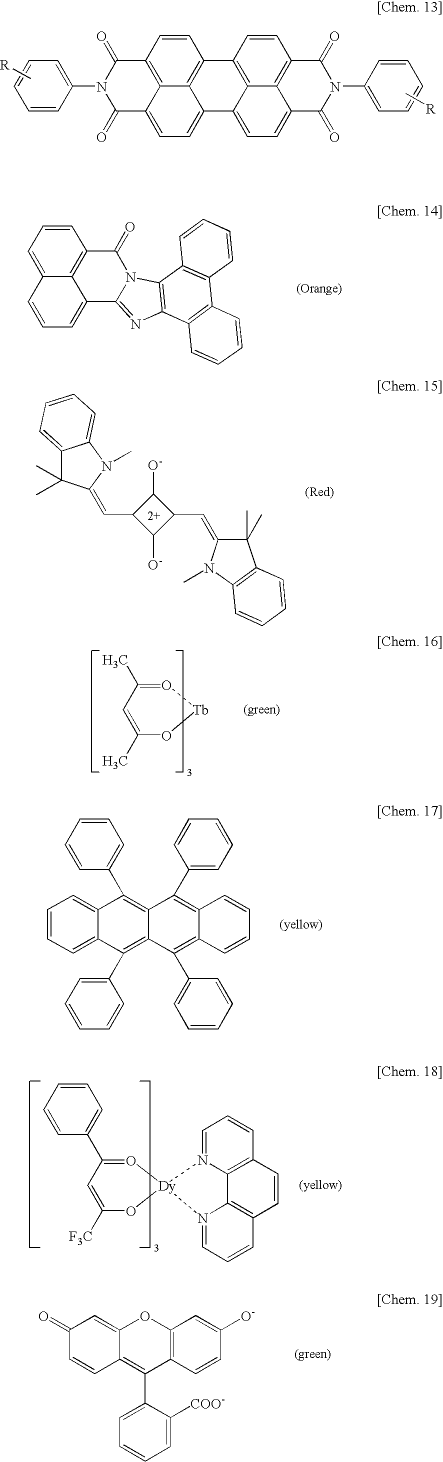

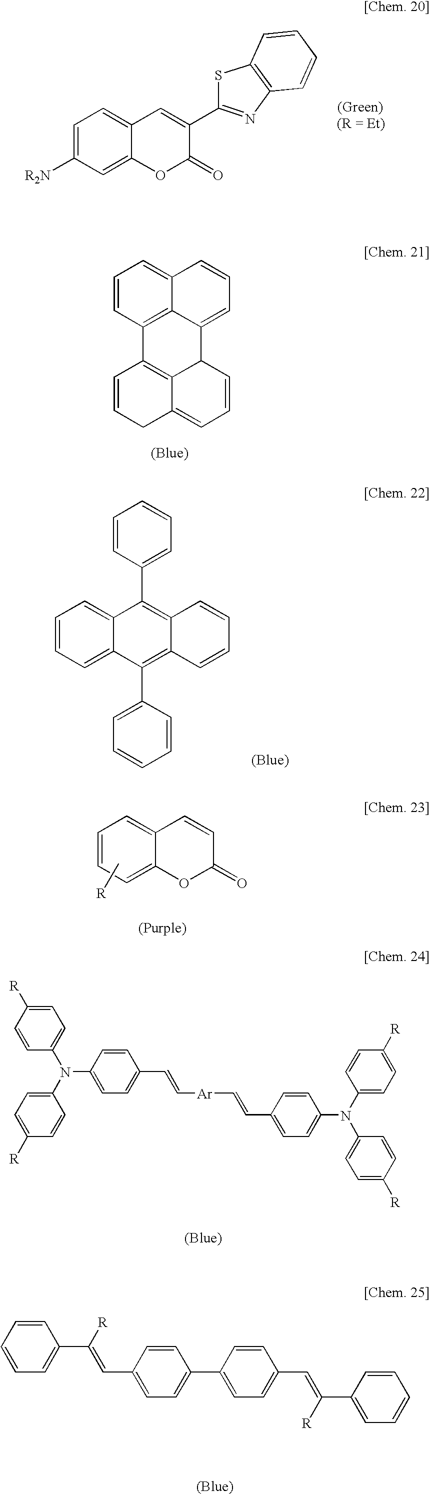

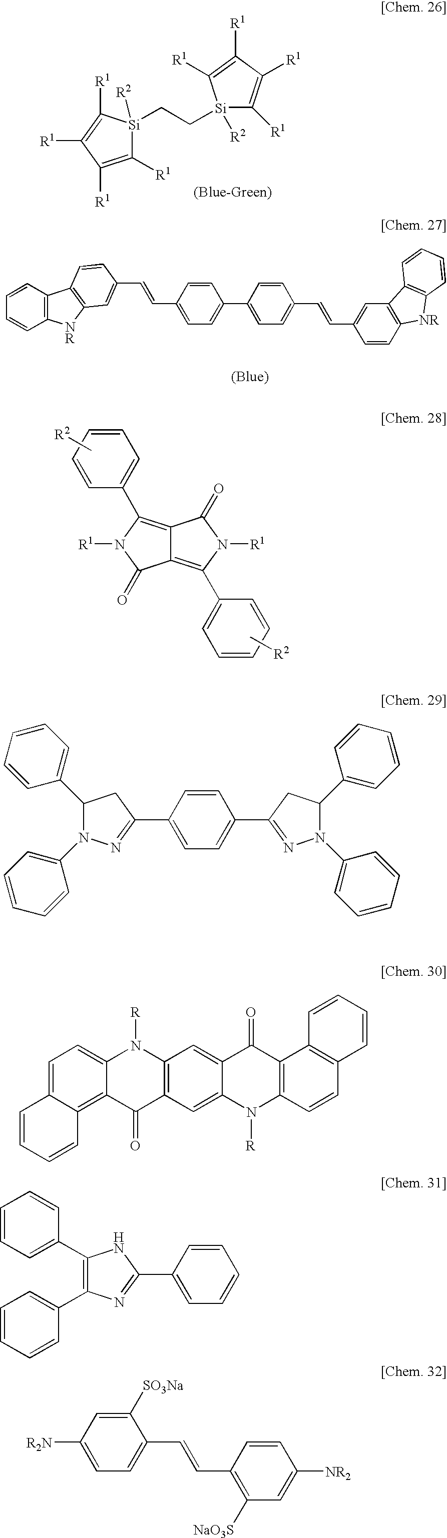

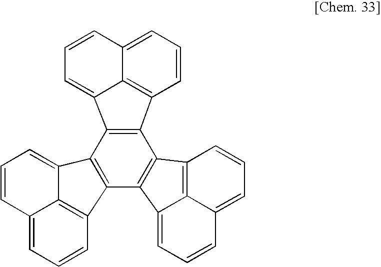

Further, the structure of this embodiment can be freely combined with any of Embodiments 1 to 3.

### Embodiment 5

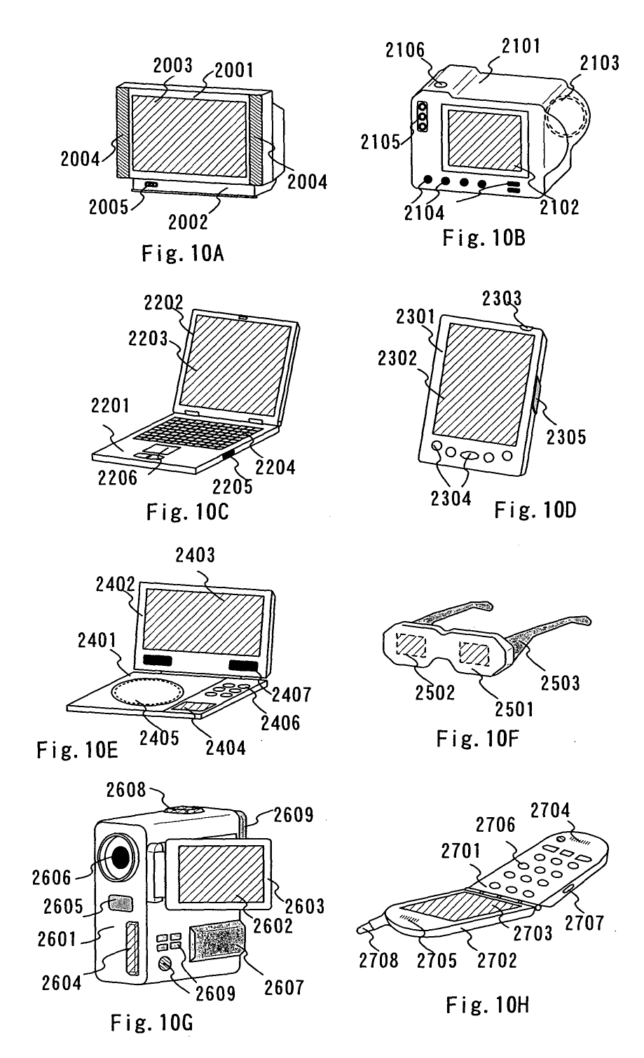

The unit of the electronic apparatuses can increase the reliability by using a light-emitting device of the present invention. Given as examples of electronic apparatuses that employ the light-emitting device manufactured in accordance with the present invention are video cameras, digital cameras, goggle type displays (head mounted displays), navigation systems, audio reproducing devices (such as car audio and audio components), laptop computers, game machines, portable information terminals (such as mobile computers, cellular phones, portable game machines, and electronic books), and image reproducing devices equipped with recording media (specifically, devices with a display device that can reproduce data in a recording medium such as a digital versatile disk (DVD) to display an image of the data). Specific examples of these electronic apparatuses are shown in FIGS. 10A to 10H.

FIG. 10A shows a display device including a case 2001, a support base 2002, a display unit 2003, speaker units 2004, a video input terminal 2005, etc. The light-emitting device of the present invention can be applied to the display unit 2003. In addition, the display device shown in FIG. 10A can be completed by the present invention. The display device refers to all display devices for displaying information, including ones for personal computers, for TV broadcasting reception, and for advertisement.

FIG. 10B shows a digital still camera including a main body 2101, a display unit 2102, an image receiving unit 2103, operation keys 2104, an external connection port 2105, a shutter 2106, etc. The light-emitting device of the present invention can be applied to the display unit 2102. The digital still camera shown in FIG. 10B can be completed by the present invention.

FIG. 10C shows a laptop computer including a main body 2201, a case 2202, a display unit 2203, a keyboard 2204, an external connection port 2205, a pointing mouse 2206 etc. The light-emitting device of the present invention can be applied to the display unit 2203. The laptop computer shown in FIG. 10C can be completed by the present invention.

FIG. 10D shows a mobile computer including a main body 2301, a display unit 2302, a switch 2303, operation keys 2304, an infrared port 2305, etc. The light-emitting device of the present invention can be applied to the display unit 2302. The mobile computer shown in FIG. 10D can be completed by the present invention.

FIG. 10E shows a portable image reproducing device equipped with a recording medium (a DVD player, to be specific). The device includes a main body 2401, a case 2402, a display unit A 2403, a display unit B 2404, a recording medium (DVD or the like) reading unit 2405, operation keys 2406, speaker units 2407, etc. The display unit A 2403 mainly displays image information whereas the display unit B 2404 mainly displays text information. The light-emitting device of the present invention can be applied to the display units A 2403 and B 2404. The image reproducing device equipped with a recording medium also includes home-video game machines. The DVD player shown in FIG. 10E can be completed by the present invention.

FIG. 10F shows a goggle type display (head mounted display) including a main body 2501, display units 2502, and arm units 2503. The light-emitting device of the present invention can be applied to the display units 2502. The goggle type display shown in FIG. 10F can be completed by the present invention.

FIG. 10G shows a video camera including a main body 2601, a display unit 2602, a case 2603, an external connection port 2604, a remote control receiving unit 2605, an image receiving unit 2606, a battery 2607, an audio input unit 2608, operation keys 2609, an eye piece 2610 etc. The light-emitting device of the present invention can be applied to the display unit 2602. The video camera shown in FIG. 10G can be completed by the present invention.

FIG. 10H shows a cellular phone including a main body 2701, a case 2702, a display unit 2703, an audio input unit 2704, an audio output unit 2705, operation keys 2706, an external connection port 2707, an antenna 2708, etc. The light-emitting device of the present invention can be applied to the display unit 2703. When the display unit 2703 displays white letters on a black background, the cellular phone may consume less power. The cellular phone shown in FIG. 10H can be completed by the present invention.

As set forth above, the present invention can be applied variously to a wide range of electronic apparatuses in all fields. The electronic apparatuses in this embodiment can be obtained by utilizing the structure of a light-emitting device shown in Embodiments 1 to 4.

### Embodiment 6

The electronic apparatuses represented in Embodiment Mode 5 include a module in which an IC such as a controller, and a power source circuit is mounted on a panel in which a light-emitting element is sealed. The module and the panel are both corresponding to one mode of the light-emitting device. In the present invention, a specific configuration of the module will be described.

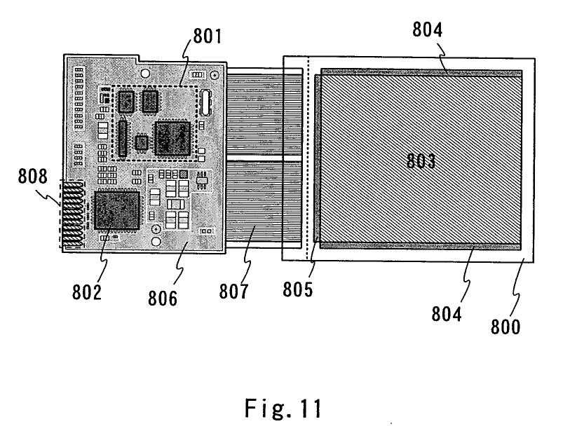

FIG. 11 shows an appearance of a module in which a panel 800 is provided with a controller 801 and a power source circuit 802. There are provided in the panel 800 a pixel portion 803 in which a light-emitting element is provided in each pixel, a scanning line driving circuit 804 for selecting a pixel in the pixel portion 803, and a signal line driving circuit 805 for supplying a video signal to the selected pixel.

The controller 801 and the power source circuit 802 are provided in a printed substrate 806, various kinds of signals and source voltage output from the controller 801 or the power source circuit 802 are supplied through FPC 807 to the pixel portion 803, the scanning line driving circuit 804, and the signal line driving circuit 805.

Through an interface (I/F) 808 in which a plurality of input terminal is arranged, source voltage and various kind of signals to the printed circuit 806 is supplied.

Although the printed substrate 806 is attached to the panel 800 with FPC in the present embodiment, the present invention is not limited to this configuration. The controller 801 and the power source circuit 802 may be provided directly in the panel 800 with COG (Chip on Class) manner.

Further, in the printed circuit 806, there is a case that a capacity formed between leading wirings and a resistance of a wiring itself cause a noise to a source voltage or a signal, or make a rise of a signal dull. Therefore, it may be prevent the noise to the power source potential or a signal and the dull rise of the signal to provide various kinds of elements such as a capacitor and a buffer in the printed substrate 806.

Still, the present embodiment can be combined with Embodiment 1 to 4.

### Embodiment 7

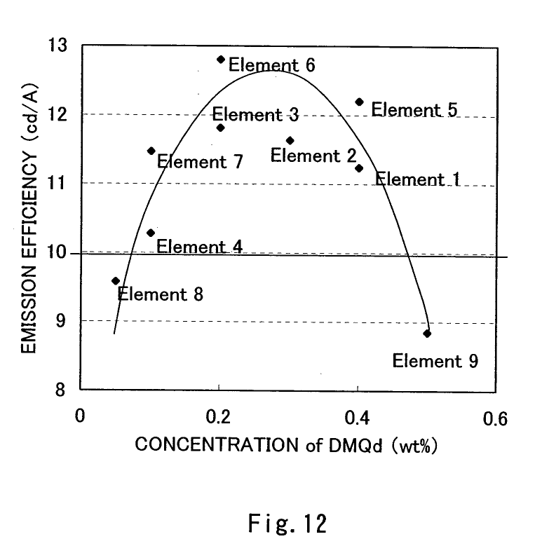

In the next place, in FIG. 12, relationship of emission efficiency (cd/A) and concentration (% by weight) of quinacridone derivative (DMQd) that is doped in Alq₃ is shown. The light-emitting elements shown with Element 1 through Element 9 have the configuration such as shown in FIG. 2. Specifically, on an anode 100 that is made of ITO that is a transparent conductive film, CuPc having a film thickness of 20 nm as a hole injection layer 101, α-NPD having a film thickness of 60 nm as a hole transporting layer 102, DMQd-added Alq₃ having a film thickness of 37.5 nm as a light-emitting layer 103, Alq₃ having a film thickness of 37.5 nm as an electron transporting layer 104, CaF₂ having a film thickness of 1 nm as an electron injection layer 105, and cathode 106 made of Al are sequentially laminated. The quinacridone derivative that is added to the light-emitting layer 103 has a structure where R in kagaku 1 is CH₃.

The concentration of DMQd is set at 0.4% by weight for the Element 1; 0.3% by weight for the Element 2; 0.2% by weight for the Element 3, 0.1% by weight for the Element 4; 0.4% by weight for the Element 5; 0.2% by weight for the Element 6; 0.1% by weight for the Element 7; 0.05% by weight for the Element 8; and 0.5% by weight for the Element 9. Furthermore, the deposition rate of the light-emitting layer 103 is set at 0.2 nm/sec for the Elements 1 through 4; 0.6 nm/sec for the Element 5 through 8; and 0.1 nm/sec for the Element 9.

Specifically, the respective deposition rates of Alq₃ and DMQd are set at 0.2 nm/sec and 8×10⁻⁴ nm/sec for the Element 1; 0.2 nm/sec and 6×10⁻⁴ nm/sec for the Element 2; 0.2 nm/sec and 4×10⁻⁴ nm/sec for the Element 3; 0.2 nm/sec and 2×10⁻⁴ nm/sec for the Element 4; 0.6 nm/sec and 2.4×10⁻³ nm/sec for the Element 5; 0.6 nm/sec and 1.2×10⁻³ nm/sec for the Element 6; 0.6 nm/sec and 6×10⁻⁴ nm/sec for the Element 7; 0.6 nm/sec and 3×10⁻⁴ nm/sec for the Element 8; and 0.1 nm/sec and 5×10⁻⁴ nm/sec for the Element 9.

As obvious from FIG. 12, while the light-emitting efficiency is higher than 10 cd/A when the concentration of DMQd is 0.1% by weight or more and 0.4% by weight or less, the light-emitting efficiency is lower than 10 cd/A when the concentration of DMQd is less than 0.1% by weight or higher than 0.4% by weight. Accordingly, it is understood that the light-emitting efficiency deteriorates when the concentration of DMQd is too high or too low. Accordingly, from FIG. 12, it is found that in order to heighten the light-emitting efficiency, the concentration of the dopant is desirably 0.1% by weight or more and 0.4% by weight or less.

What is claimed is:

1. A light-emitting device comprising:
a first passivation film and a second passivation film; and
a light-emitting element formed between the first passivation film and the second passivation film,
wherein the light-emitting element comprises an anode, a cathode and a light-emitting layer between the anode and the cathode;
wherein the light-emitting layer comprises a dopant at a concentration of 0.1% by weight or more and 0.4% by weight or less.

2. A light-emitting device comprising:
a first passivation film and a second passivation film;
a photosensitive organic resin film having an opening; and
a light-emitting element having an anode, a cathode and a light-emitting layer between the anode and the cathode,
wherein the light-emitting layer comprises a dopant at a concentration of 0.1% by weight or more and 0.4% by weight or less;
wherein the anode and the photosensitive organic resin film are formed on the first passivation film;
wherein the anode, the cathode and the light-emitting layer are overlapped in the opening,
wherein the photosensitive organic resin film and the cathode are covered with the second passivation film.

3. A light-emitting device according to claim 2, wherein a radius of curvature of a curve that a section in the opening of the photosensitive organic resin film depicts is in the range of from 0.2 to 2 μm.

4. A light-emitting device according to claim 2, wherein the photosensitive organic resin film has positive photosensitivity.

5. A light-emitting device according to claim 2, wherein the photosensitive organic resin film has negative photosensitivity.

6. A light-emitting device according to any one of claims 1 and 2, wherein at least one of the first passivation film and the second passivation film is a carbon nitride film or a silicon nitride film formed by an RF sputtering process.

7. A light-emitting device according to any one of claims 1 and 2, wherein at least one of the first passivation film and the second passivation film comprises a material selected from the group consisting of DLC, boron nitride and alumina.

8. A light-emitting device as according to any one of claim 1 and 2, wherein the light-emitting device includes a transistor that controls a current that is supplied to the light-emitting element, and
wherein the transistor is operated in a saturation region.

9. A light-emitting device according to any one of claims 1 and 2,
wherein the light-emitting element, after turning on for 100 hr with an initial intrinsic brightness set at 320 cd/mm² and a duty ratio set at 70%, has a diminishing amount of the intrinsic brightness of substantially 10% or less of the initial intrinsic brightness.

10. A light-emitting device according to any one of claims 1 and 2,
wherein the light-emitting element, after turning on for 1000 hr with an initial intrinsic brightness set at 320 cd/mm² and a duty ratio set at 70%, has a diminishing amount of the intrinsic brightness of substantially 20% or less of the initial intrinsic brightness.

11. A light-emitting device according to any one of claims 1 and 2,
wherein the light-emitting device includes a transistor that controls a current that is supplied to the light-emitting element,
wherein both the light-emitting element and the transistor are plurally disposed in a pixel portion of the light-emitting device,
wherein the pixel portion is disposed on a substrate, and
wherein when brightness of the light-emitting element is set at 200 nt when a duty ratio is set at 70%, a temperature of a portion that overlaps with the pixel portion of the substrate is 40 degree centigrade or less.

12. A light-emitting device according to any one of claims 1 and 2,
wherein the light-emitting device includes a transistor that controls a current that is supplied to the light-emitting element,
wherein both the light-emitting element and the transistor are plurally disposed in a pixel portion of the light-emitting device,
wherein the pixel portion is disposed on a substrate,
wherein when power consumption of the light-emitting element and the transistor is set at 600 mW when a duty ratio is set at 70%, a temperature of a portion that overlaps with the pixel portion of the substrate is 40 degree centigrade or less.

13. A light-emitting device as set forth in any one of claims 1 through 8:
wherein the light-emitting device includes a transistor that controls a current that is supplied to the light-emitting element;
both the light-emitting element and the transistor are plurally disposed in a pixel portion of the light-emitting device; and
the pixel portion is disposed on a substrate;
wherein when brightness of the light-emitting element is set at 130 nt when a duty ratio is set at 70%, a temperature of a portion that overlaps with the pixel portion of the substrate is 35 degree centigrade or less.

14. A light-emitting device according to any one of claims 1 and 2,
wherein the light-emitting device includes a transistor that controls a current that is supplied to the light-emitting element,
wherein both the light-emitting element and the transistor are plurally disposed in a pixel portion of the light-emitting device,
wherein the pixel portion is disposed on a substrate, and
wherein when power consumption of the light-emitting element and the transistor is set at 400 mW when a duty ratio is set at 70%, a temperature of a portion that overlaps with the pixel portion of the substrate is 35 degree centigrade or less.

15. A light-emitting device according to any one of claims 1 and 2, wherein the light-emitting layer comprises a quinacridone derivative.

16. A method of manufacturing a light-emitting device that includes an anode, a cathode and a light-emitting element disposed between the anode and the cathode, comprising:
forming the anode on a first passivation film;
forming a photosensitive organic resin film over the anode;
forming an opening partially in the photosensitive organic resin film by exposure so that the anode is partially exposed;
heating the organic resin film under a vacuum atmosphere;
forming a light-emitting layer having a dopant concentration of 0.1% by weight or more and 0.4% by weight or less over the organic resin film and the anode;
forming the cathode over the light-emitting layer so that the anode, the cathode and the light-emitting layer are overlapped in the opening; and
forming a second passivation film over the organic resin film and the cathode.

17. A method of manufacturing a light-emitting device according to claim 16, wherein the vacuum atmosphere is a vacuum of 3×10⁻⁷ Torr or less.

18. A method of manufacturing a light-emitting device according to claim 16, wherein at least one of the first passivation film and the second passivation film is a carbon nitride film or a silicon nitride film deposited by an RF sputtering process.

19. A method of manufacturing a light-emitting device according to claim 16, wherein at least one of the first passivation film and the second passivation film comprises a material selected from the group consisting of DLC, boron nitride and alumina.

20. A method of manufacturing a light-emitting device according to claim 16, wherein a radius of curvature of a curve that a section in the opening of the organic resin film depicts is in the range of from 0.2 to 2 μm.

21. A method of manufacturing a light-emitting device according to claim 16, wherein the organic resin film has positive photosensitivity.

22. A method of manufacturing a light-emitting device according to claim 16, wherein the organic resin film has negative photosensitivity.
